(19) United States
(12) Patent Application Publication
(10) Pub. No.: US 2026/0262259 A1
(43) Pub. Date: Sep. 3, 2026

(54) SEMICONDUCTOR STORAGE DEVICE AND MANUFACTURING METHOD OF SEMICONDUCTOR STORAGE DEVICE

(71) Applicant: Kioxia Corporation, Tokyo (JP)

(72) Inventors: Noritaka ISHIHARA, Nagoya Aichi (JP); Sho MORITA, Kuwana Mie (JP)

(21) Appl. No.: 19/326,406

(22) Filed: Sep. 11, 2025

(30) Foreign Application Priority Data
Feb. 28, 2025 (JP) 2025-031521

(51) Int. Cl. H10D 30/69; G11C 5/06; H10B 43/27; H10B 43/35; H10B 43/40; H10D 30/01; H10D 62/40; H10D 62/60; H10D 62/834

(52) U.S. Cl. CPC H10D 30/693; G11C 5/063; H10B 43/27; H10B 43/35; H10D 30/0413; H10D 62/40; H10D 62/60; H10D 62/834; H10B 43/40

(57) ABSTRACT

A semiconductor storage device with improved crystallinity of a channel layer is provided. A semiconductor storage device includes a stacked body including a plurality of conductive layers and a plurality of insulating layers that are stacked alternately with each other and a pillar extending in the stacked body in a stacked direction of the stacked body. The pillar includes a first semiconductor layer extending in the stacked body in the stacked direction, a second semiconductor layer above the first semiconductor layer, and a third semiconductor layer interposed between the first and second semiconductor layers. The third semiconductor layer contains an additive of at least one of carbon, nitrogen, oxygen, and fluorine.

### CROSS-REFERENCE TO RELATED APPLICATIONS

This application is based upon and claims the benefit of priority from Japanese Patent Application No. 2025-031521, filed Feb. 28, 2025, the entire contents of which are incorporated herein by reference.

### FIELD

Embodiments described herein relate generally to a semiconductor storage device and a manufacturing method of a semiconductor storage device.

### BACKGROUND

In three-dimensional non-volatile memory, a plurality of memory cells, each of which includes a channel layer, are arranged along the height direction of a pillar on a side surface of the pillar that extends in the height direction. Here, while it is a practice to crystallize the channel layer to improve memory cell characteristics, incomplete crystallization may cause variation in the memory cell characteristics.

### BRIEF DESCRIPTION OF THE DRAWINGS

FIG. 1 shows diagrams illustrating a schematic example of configuration of a semiconductor storage device according to an embodiment.

FIG. 2 shows cross-sectional views of an example of configuration of the semiconductor storage device according to the embodiment.

FIG. 3 shows diagrams sequentially illustrating part of procedures of a manufacturing method of the semiconductor storage device according to the embodiment.

FIG. 4 shows diagrams sequentially illustrating part of procedures of a manufacturing method of the semiconductor storage device according to the embodiment.

FIG. 5 shows diagrams sequentially illustrating part of procedures of a manufacturing method of the semiconductor storage device according to the embodiment.

FIG. 6 shows diagrams sequentially illustrating part of procedures of a manufacturing method of the semiconductor storage device according to the embodiment.

FIG. 7 shows diagrams sequentially illustrating part of procedures of a manufacturing method of the semiconductor storage device according to the embodiment.

FIG. 8 shows diagrams sequentially illustrating part of procedures of a manufacturing method of the semiconductor storage device according to the embodiment.

FIG. 9 shows diagrams sequentially illustrating part of procedures of a manufacturing method of the semiconductor storage device according to the embodiment.

FIG. 10 shows diagrams sequentially illustrating part of procedures of a manufacturing method of the semiconductor storage device according to the embodiment.

FIG. 11 shows diagrams sequentially illustrating part of procedures of a manufacturing method of the semiconductor storage device according to the embodiment.

FIG. 12 shows diagrams sequentially illustrating part of procedures of a manufacturing method of the semiconductor storage device according to the embodiment.

### DETAILED DESCRIPTION

An object of an embodiment is to provide a semiconductor storage device and a manufacturing method of a semiconductor storage device, which make it possible to improve crystallinity of a channel layer.

In general, according to an embodiment, a semiconductor storage device includes: a stacked body including a plurality of conductive layers and a plurality of insulating layers that are stacked alternately with each other; and a pillar extending in the stacked body in a stacked direction of the stacked body, the pillar includes: a first semiconductor layer extending in the stacked body in the stacked direction; a second semiconductor layer above the first semiconductor layer; and a third semiconductor layer interposed between the first and second semiconductor layers, and the third semiconductor layer contains an additive of at least one of carbon, nitrogen, oxygen, and fluorine.

Embodiments of the invention will now be described in detail with reference to the drawings. The embodiments described below are not intended to limit the invention. The constituent elements in the embodiments described below include those readily conceivable by those skilled in the art or those that are substantially the same.

### EMBODIMENTS

Embodiments will now be described in detail with reference to the drawings.

### (Example of Configuration of Semiconductor Storage Device)

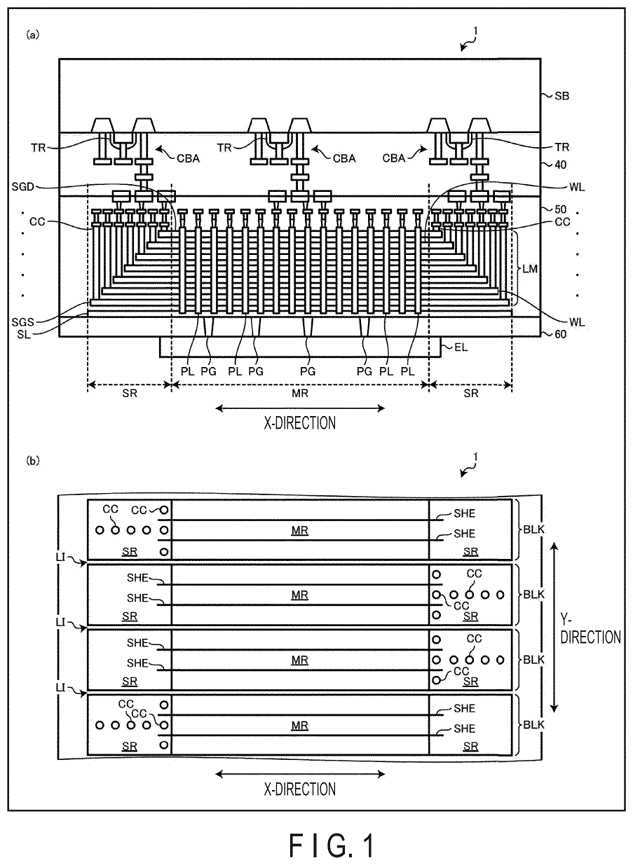

FIG. 1 shows diagrams illustrating a schematic example of configuration of a semiconductor storage device 1 according to an embodiment. More specifically, the part (a) of FIG. 1 illustrates a cross-sectional view taken along an X-direction of the semiconductor storage device 1, and the part (b) of FIG. 1 schematically illustrates a plan view of the semiconductor storage device 1.

In the part (a) of FIG. 1, hatching is not indicated in consideration of clarity of the drawing. Furthermore, in the part (a) of FIG. 1, components that do not necessarily exist in the same section are illustrated and some of upper-layer wires and the like are not illustrated.

In the specification, both the X-direction and a Y-direction are directions parallel to a surface of a word line WL, and the X-direction and the Y-direction are perpendicular to each other. In addition, an electrically drawn direction of the word line WL may be referred to as a first direction and the first direction is a direction along the X-direction. Furthermore, a direction that intersects with the first direction may be referred to as a second direction and the second direction is a direction along the Y-direction. It is noted that the semiconductor storage device 1 may include manufacturing errors, and therefore, the first direction and the second direction are not necessarily perpendicular to each other.

As illustrated in the part (a) of FIG. 1, the semiconductor storage device 1 includes an electrode film EL, a source line SL, one or more select gate lines SGS, a plurality of word lines WL, one or more select gate lines SGD, and a semiconductor substrate SB provided with a peripheral circuit CBA in this order from the bottom of the paper.

The source line SL is arranged on the electrode film EL with an insulating layer 60 in between. A plurality of plugs PG are arranged in the insulating layer 60, and electrical conduction is maintained between the source line SL and the electrode film EL through the plugs PG. Although not illustrated, an electrode pad is provided on the same layer as the electrode film EL to supply power and signals to the semiconductor storage device 1 from outside. The select gate line SGS, the plurality of word lines WL, and the select gate line SGD are stacked on the source line SL in this order.

As illustrated in the parts (a) and (b) of FIG. 1, a memory region MR is arranged in the center portion of the plurality of word lines WL and the like in the X-direction and a stepped region SR is arranged at each of opposite ends of the plurality of word lines WL and the like in the X-direction. The memory region MR and the stepped region SR are divided into a plurality of regions by a plurality of plate-shaped contacts LI that pass through the plurality of word lines WL and the like and extend in a direction along the X-direction.

Here, a region that is located between the plate-shaped contacts LI that are adjacent to each other in the Y-direction and includes the memory region MR and the stepped region SR is referred to as a block region BLK. As described below, a plurality of memory cells that retain data in a non-volatile manner are included in the memory region MR, and the block region BLK serves as an erase unit for the data.

Furthermore, a plurality of separating layers SHE that pass through the select gate line SGD and extend in a direction along the X-direction are arranged between the plate-shaped contacts LI that are adjacent to each other in the Y-direction. The plurality of separating layers SHE extend in a direction along the X-direction all the way through the memory region MR up to a part of the stepped region SR at each of opposite ends in the X-direction.

A plurality of pillars PL, which pass through the word line WL and the select gate lines SGD and SGS in their stacked direction, are arranged in the memory region MR. The lower end of the pillar PL reaches the source line SL. A plurality of memory cells are formed at intersections between the pillars PL and the word lines WL. In this way, the semiconductor storage device 1 is configured, for example, as a three-dimensional non-volatile memory in which memory cells are three-dimensionally arranged in the memory region MR.

In the stepped region SR, the plurality of word lines WL and the select gate lines SGD and SGS are processed and terminated in a stepped shape. Here, as the distance increases from the memory region MR in the X-direction, the plurality of word lines WL and the select gate lines SGD and SGS that present terrace portions change from those on the upper layer side to those on the lower layer side, so that the height position of the terrace portion is lowered toward the source line SL.

In the specification, the direction in which terrace surfaces of the plurality of word lines WL and the select gate lines SGD and SGS are facing is defined as the upper side of the semiconductor storage device 1.

The separating layer SHE described above extends from the memory region MR up to a portion in which the select gate line SGD of the stepped region SR is processed in a stepped shape. In this way, the select gate line SGD is separated into a plurality of regions in one block region BLK. In other words, the separating layer SHE passes through upper layer portions than the plurality of word lines WL, so that the upper layer portions are partitioned into a plurality of patterns of the select gate line SGD.

Contacts CC, each of which is connected to the word line WL and the select gate lines SGD and SGS of each layer, are arranged on the terrace portions, each step of which is presented by the plurality of word lines WL and the select gate lines SGD and SGS. One contact CC per layer is connected on the word line WL and the select gate line SGS. On the select gate line SGD, one contact CC per partition that is separated by the separating layer SHE is connected per layer.

Here, in one block region BLK, a plurality of contacts CC are arranged on one stepped region SR of the stepped regions SR on opposite sides in the X-direction. Furthermore, when viewed on one side of the X-direction, for example, the plurality of contacts CC are arranged in two consecutive block regions BLK every four block regions BLK.

Specifically, in the example of the part (b) of FIG. 1, in the topmost block region BLK in the paper, the plurality of contacts CC are arranged in the stepped region SR to the left of the paper, for example, out of the stepped regions SR on opposite ends in the X-direction. Furthermore, in the block regions BLK, one of which is immediately below and one of which is two block regions BLK down from the above-described block region BLK, the plurality of contacts CC are arranged in the stepped regions SR to the right of the paper out of the stepped regions SR on opposite ends in the X-direction. Furthermore, in the bottommost block region BLK in the paper, the plurality of contacts CC are arranged in the stepped region SR to the left of the paper again.

Accordingly, each of the contacts CC in the stepped regions SR on opposite ends in the X-direction illustrated in the part (a) of FIG. 1 belongs to a different block region BLK and is not located on the same section in practice.

Through the contacts CC, lines such as the word line WL, which are stacked in a multi-layered manner, are brought out independently. More specifically, write voltage, read voltage, and the like are applied from the contacts CC to a memory cell included in the memory region MR in the center portion of the plurality of word lines WL through the word line WL at the same height position as the memory cell.

The plurality of word lines WL and the select gate lines SGD and SGS, the pillar PL, and the contact CC are covered with an insulating layer 50. The insulating layer 50 extends in the vicinity of those components including the plurality of word lines WL and the like.

The semiconductor substrate SB above the insulating layer 50 that covers the components is, for example, a silicon substrate. The peripheral circuit CBA that includes a transistor TR, a wire, and the like is arranged on the surface of the semiconductor substrate SB. Various types of voltage applied from the contacts CC to the memory cell are controlled by the peripheral circuit CBA that is electrically connected to the contacts CC. In this way, the peripheral circuit CBA controls electrical operation of the memory cell.

The peripheral circuit CBA is covered with an insulating layer 40. The insulating layer 40 and the insulating layer 50 that covers the plurality of word lines WL and the like are joined together to form the semiconductor storage device 1 including components such as the plurality of word lines WL and the select gate lines SGD and SGS, the pillar PL, and the contact CC and the peripheral circuit CBA.

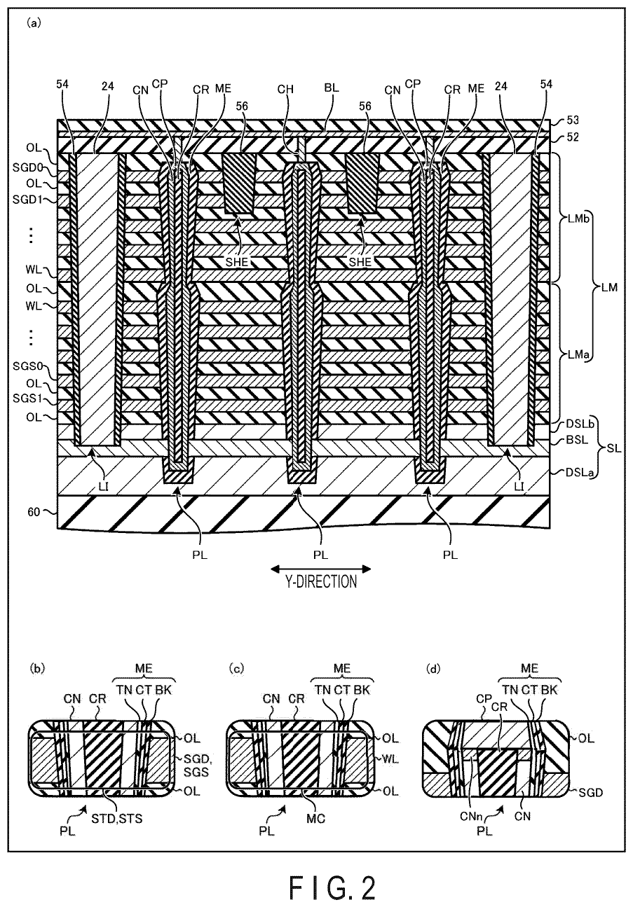

Next, with reference to FIG. 2, a detailed example of configuration of the semiconductor storage device 1 will be described. FIG. 2 shows cross-sectional views of an example of configuration of the semiconductor storage device 1 according to the embodiment.

More specifically, the part (a) of FIG. 2 illustrates a cross-sectional view of the memory region MR of the semiconductor storage device 1 taken along the Y-direction. In the part (a) of FIG. 2, structures below the insulating layer 60 and those above an insulating layer 53 described below are not illustrated.

The part (b) of FIG. 2 illustrates an enlarged cross-sectional view of the pillar PL at the height position of the select gate lines SGD and SGS. The part (c) of FIG. 2 illustrates an enlarged cross-sectional view of the pillar PL at the height position of the word line WL. The part (d) of FIG. 2 illustrates an enlarged cross-sectional view of the pillar PL at the height position of the topmost insulating layer OL.

As illustrated in the part (a) of FIG. 2, the source line SL has a multi-layered structure of a lower source line DSLa, an intermediate source line BSL, and an upper source line DSLb stacked on the insulating layer 60 in this order, for example. The lower source line DSLa, the intermediate source line BSL, and the upper source line DSLb are, for example, a polysilicon layer. Among them, at least the intermediate source line BSL may be a conductive polysilicon layer and the like into which impurities are diffused.

The source line SL is connected to the peripheral circuit CBA with the electrode film EL in between by a through-hole contact (not illustrated) that extends from the electrode film EL to the peripheral circuit CBA in the above-described insulating layer 50 outside a stacked body LM.

The stacked body LM is arranged on the source line SL. The stacked body LM includes the stacked bodies LMa and LMb of the plurality of word lines WL and a plurality of insulating layers OL stacked alternately, with one word line WL on top of one insulating layer OL, or vice versa.

The stacked body LMa is arranged above the source line SL. In further lower tiers under the bottommost word line WL of the stacked body LMa, a plurality of select gate lines SGS0 and SGS1 are arranged from the upper layer side of the stacked body LMa in this order with the insulating layer OL in between. The stacked body LMb is arranged on the stacked body LMa. In further upper tiers above the topmost word line WL of the stacked body LMb, a plurality of select gate lines SGD0 and SGD1 are arranged from the upper layer side of the stacked body LMb in this order with the insulating layer OL in between.

Here, any number of the word line WL and the select gate lines SGD and SGS may be stacked in the stacked body LM. The word line WL and the select gate lines SGD and SGS are, for example, a tungsten layer or a molybdenum layer. The insulating layer OL is, for example, a silicon oxide layer.

The upper surface of the stacked body LM is covered with insulating layers 52 and 53 in this order. The insulating layers 52 and 53 each constitute a part of the insulating layer 50 in FIG. 1.

As described above, the stacked body LM is divided by the plurality of plate-shaped contacts LI in the Y-direction. That is, the plate-shaped contacts LI are aligned in the Y-direction one another and each extend in a direction along the stacked direction of the stacked body LM and the X-direction.

As described above, the plate-shaped contact LI continuously extends in the stacked body LM from one end to the other end of the stacked body LM in the X-direction. Furthermore, the plate-shaped contact LI passes through the stacked body LM and the upper source line DSLb and reaches the intermediate source line BSL in the memory region MR.

Furthermore, the plate-shaped contact LI has a tapered shape such that the width in the Y-direction is reduced, for example, from the upper end portion toward the lower end portion. Alternatively, the plate-shaped contact LI has a bowing shape such that the width in the Y-direction is maximized, for example, at a predetermined position between the upper end portion and the lower end portion.

Each of the plate-shaped contacts LI includes an insulating layer 54 and a conductive layer 24. The insulating layer 54 is, for example, a silicon oxide layer. The conductive layer 24 is, for example, a tungsten layer or a conductive polysilicon layer.

The insulating layer 54 covers side walls of the plate-shaped contact LI facing each other in the Y-direction. The conductive layer 24 fills farther inward than the insulating layers 54 that cover the side walls of the plate-shaped contact LI and is electrically connected to the source line SL including the intermediate source line BSL.

Here, in place of the plate-shaped contact LI, a plate-shaped member filled with an insulating layer may pass through the stacked body LM and extends in a direction along the X-direction, so as to divide the stacked body LM in the Y-direction.

The plurality of separating layers SHE, which pass through the upper layer portion of the stacked body LMb and extend in a direction along the X-direction, are arranged between the plate-shaped contacts LI that are adjacent to each other in the Y-direction. The separating layers SHE are insulating layers 56 such as a silicon oxide layer, which pass through the select gate lines SGD0 and SGD1 and reach the insulating layer OL immediately under the select gate line SGD1.

In other words, the separating layers SHE, which pass through the upper layer portion of the stacked body LMb, extend in the X-direction between the plate-shaped contacts LI through the memory region MR and a part of the stepped region SR, so that the upper layer portion of the stacked body LMb is partitioned into the select gate lines SGD0 and SGD1 as described above.

The plurality of pillars PL are arranged in a distributed manner in the memory region MR, passing through the stacked body LM, the upper source line DSLb, and the intermediate source line BSL to reach the lower source line DSLa.

For example, the plurality of pillars PL form a staggered arrangement when viewed from the stacked direction of the stacked body LM. The individual pillar PL has a shape such as circular, elliptical, or oval, for example, in terms of a cross-sectional shape in a direction parallel to the layer of the stacked body LM, that is, a direction along an XY-plane.

Furthermore, the pillar PL has tapered shapes such that the diameter and the cross-sectional area are reduced from the upper layer side toward the lower layer side in a portion that passes through the stacked body LMa and in a portion that passes through the stacked body LMb, respectively. Alternatively, the pillar PL has bowing shapes such that the diameter and the cross-sectional area are maximized, for example, at a predetermined position between the upper layer side and the lower layer side in a portion that passes through the stacked body LMa and in a portion that passes through the stacked body LMb, respectively.

Each of the pillars PL includes a memory layer ME that extends in the stacked body LM in the stacked direction, a channel layer CN that extends in the stacked body LM in the stacked direction inward of the memory layer ME, a cap layer CP that covers the upper surface of the channel layer CN, and a core layer CR that serves as a core material of the pillar PL.

The channel layer CN is in direct contact with the intermediate source line BSL at a depth position of the intermediate source line BSL. That is, the memory layer ME is arranged on the side surface of the pillar PL except the depth position of the intermediate source line BSL. Furthermore, the memory layer ME is arranged on the bottom surface of the pillar PL that reaches the depth of the lower source line DSLa.

In this way, the channel layer CN is connected to the intermediate source line BSL on the side surface and further electrically connected to the entire source line SL through the intermediate source line BSL.

The cap layer CP is arranged on the upper end portion of the pillar PL, covering at least the upper end portion of the channel layer CN, and connected to the channel layer CN. Furthermore, the cap layer CP is connected to a bit line BL arranged in the insulating layer 53 through a plug CH arranged in the topmost insulating layers OL and 52 of the stacked body LM. The bit line BL extends above the stacked body LM in a direction along the Y-direction such that it intersects with the drawn direction of the word line WL.

As illustrated in the parts (b) and (c) of FIG. 2, the memory layer ME includes a stacked structure including a block insulating layer BK, a charge accumulation layer CT, and a tunnel insulating layer TN in this order from the outer peripheral side of the pillar PL. The block insulating layer BK and the tunnel insulating layer TN of the memory layer ME and the core layer CR are, for example, a silicon oxide layer. The charge accumulation layer CT is, for example, a silicon nitride layer.

The channel layer CN is a semiconductor layer with high crystallinity and is, for example, a single crystal silicon layer. It is noted that a part of the channel layer CN may include polycrystalline silicon. Even in this case, the channel layer CN preferably includes single crystal silicon as a main component.

The cap layer CP is, for example, a polycrystalline semiconductor layer such as a polysilicon layer. It is noted that a part of the cap layer CP may include a non-crystalline semiconductor such as of amorphous silicon.

As illustrated in the part (c) of FIG. 2, with a configuration described above, a memory cell MC is formed on the side surface of the pillar PL in each portion facing the individual word line WL. Data write and read are carried out on the memory cell MC by a predetermined voltage being applied from the word line WL.

As illustrated in the part (b) of FIG. 2, a select gate STD is formed at each of portions in which the side surfaces of the pillar PL face the select gate lines SGD0 and SGD1. Furthermore, a select gate STS is formed at each of portions in which the side surfaces of the pillar PL face the select gate lines SGS0 and SGS1 in lower tiers under the word line WL.

The select gates STD and STS are turned on or off by a predetermined voltage being applied from the select gate lines SGD and SGS, respectively, so that the memory cell MC of the pillar PL to which the select gate STD or STS belongs can be placed into a selected state or an unselected state.

As illustrated in the part (d) of FIG. 2, the pillar PL further includes a semiconductor layer CNn that is interposed between the channel layer CN and the cap layer CP. More specifically, the semiconductor layer CNn is located above at least the height position of the topmost word line WL of the stacked body LM, and more preferably, arranged above the height position of the topmost select gate line SGD0 of the stacked body LM and, for example, at the height position of the topmost insulating layer OL of the stacked body LM.

The semiconductor layer CNn is, for example, a single crystal silicon layer. It is noted that a part of the semiconductor layer CN may include polycrystalline silicon. Even in this case, the semiconductor layer CN preferably includes single crystal silicon as a main component.

The semiconductor layer CNn contains, for example, at least any of carbon, nitrogen, oxygen, and fluorine as an additive. The concentration of additive in the semiconductor layer CNn is, for example, 1×10²⁰ atm/cm³ or more and 3×10²¹ atm/cm³ or less, preferably 5×10²⁰ atm/cm³ or more and 2×10²¹ atm/cm³ or less, and more preferably 9×10²⁰ atm/cm³ or more and 1.5×10²¹ atm/cm³ or less.

### (Manufacturing Method of Semiconductor Storage Device)

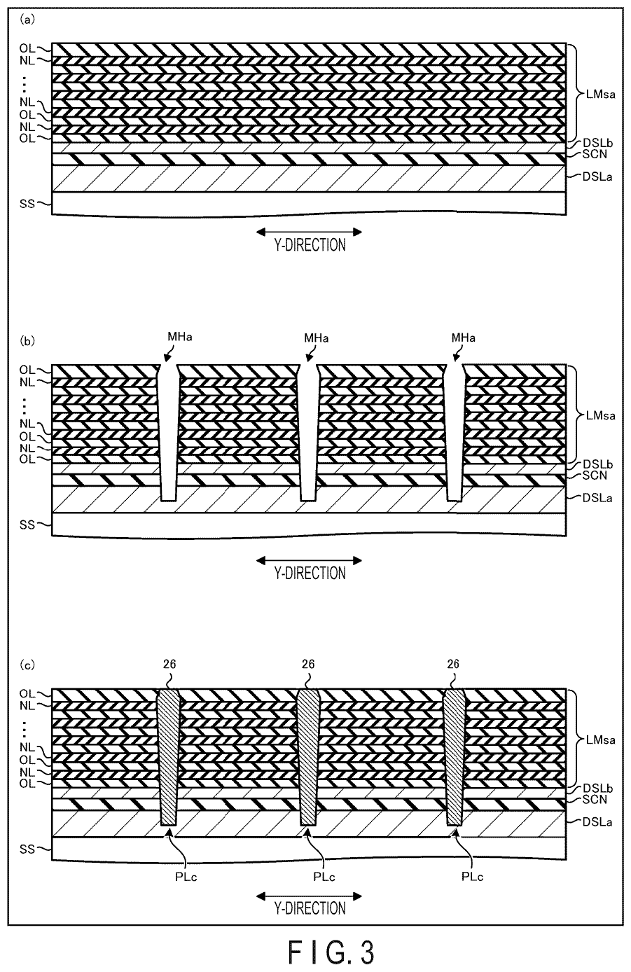

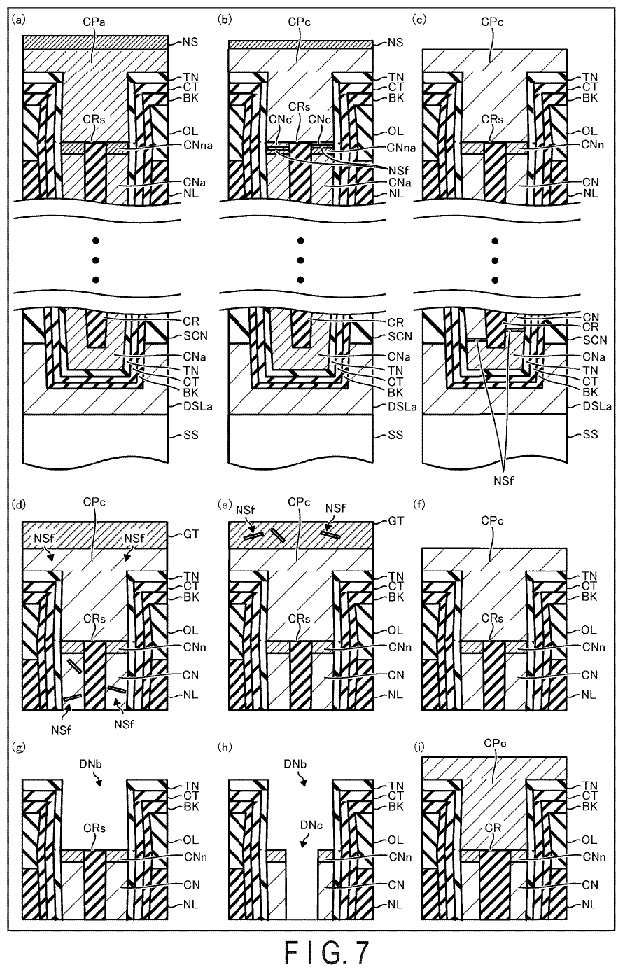

Next, a manufacturing method of the semiconductor storage device 1 according to the embodiment will be described with reference to FIGS. 3 to 12. FIGS. 3 to 12 show diagrams sequentially illustrating part of procedures of the manufacturing method of the semiconductor storage device 1 according to the embodiment. FIGS. 3 to 12 except FIG. 7 illustrate cross-sections taken along the Y-direction of a region to be the memory region MR later. FIG. 7 illustrates a partially enlarged cross-sectional view of the pillar PL during manufacturing.

As illustrated in the part (a) of FIG. 3, the lower source line DSLa, an intermediate sacrificial layer SCN, and the upper source line DSLb are formed on a support substrate SS in this order.

As the support substrate SS, a semiconductor substrate such as a silicon substrate, an insulating substrate such as a ceramic substrate, a conductive substrate, or the like may be used. The above-described insulating layer 60 (see the part (a) of FIG. 2 and the like) may be formed on the upper surface side of the support substrate SS. The intermediate sacrificial layer SCN is, for example, a silicon nitride layer and is to be replaced with a polysilicon layer and the like later to be turned into the intermediate source line BSL.

A stacked body LMsa of a plurality of insulating layers NL and the plurality of insulating layers OL stacked alternately, with one insulating layer NL on top of one insulating layer OL, or vice versa is formed on the upper source line DSLb. The insulating layer NL is, for example, a silicon nitride layer and is to be replaced with a conductive material later to function as a sacrificial layer to be turned into the word line WL or the select gate line SGS.

Thereafter, although not illustrated, the insulating layer NL and the insulating layer OL are processed into a stepped shape in a part of regions of the stacked body LMsa. Such processing can be carried out by repeating slimming of mask patterns in photoresist layers and the like and etching of the insulating layer NL and the insulating layer OL of the stacked body LMsa multiple times.

That is, a mask pattern is formed on the upper surface of the stacked body LMsa, and the insulating layer NL and the insulating layer OL in exposed portions are etched away one by one. Furthermore, processing with oxygen plasma and the like is carried out to cause ends of the mask pattern to contract, so that the upper surface of the stacked body LMsa is newly exposed, and then, the insulating layer NL and the insulating layer OL are further etched away one by one. Repeating such processing multiple times enables the formation of the stacked body LMsa that has stepped shapes on opposite ends in the X-direction.

Thereafter, the stepped shape on the opposite ends in the X-direction is covered with a part of the above-described insulating layer 50 (see the part (a) of FIG. 1).

As illustrated in the part (b) of FIG. 3, a plurality of memory holes MHa that extend through the stacked body LMsa in the stacked direction are formed. The plurality of memory holes MHa pass through the stacked body LMsa, the upper source line DSLb, and the intermediate sacrificial layer SCN and reach the lower source line DSLa. The memory holes MHa are portions that are to be lower structures of the pillars PL later.

As illustrated in the part (c) of FIG. 3, the memory holes MHa are filled with a sacrificial layer 26 such as an amorphous silicon layer or CVD carbon layer. In this way, the pillars PLc are formed in the plurality of memory holes MHa filled with the sacrificial layer 26.

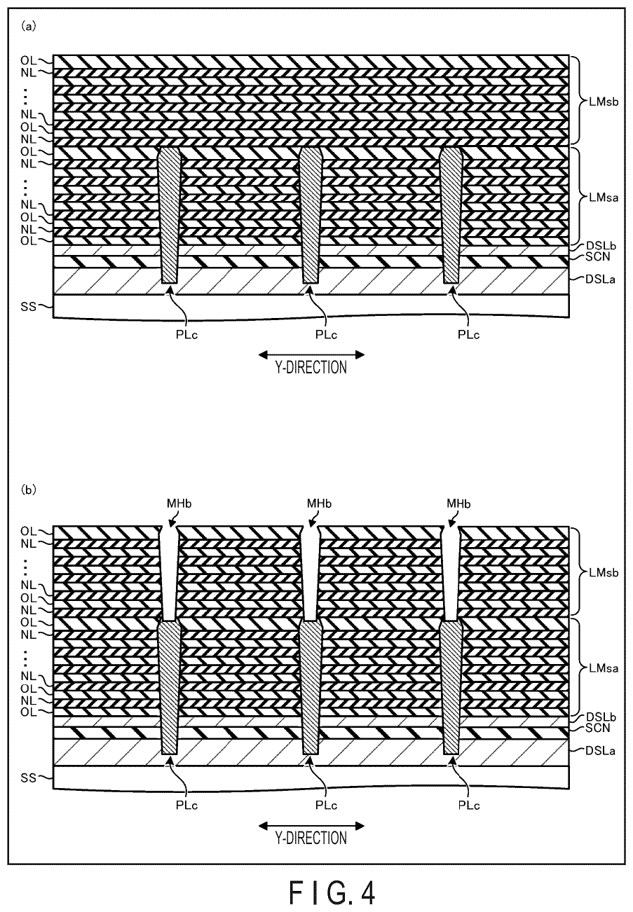

As illustrated in the part (a) of FIG. 4, a stacked body LMsb that covers the stacked body LMsa and is made up of the plurality of insulating layers NL and the plurality of insulating layers OL stacked alternately, with one insulating layer NL on top of one insulating layer OL, or vice versa is formed. The insulating layer NL of the stacked body LMsb is to be replaced with a conductive layer later to function as a sacrificial layer to be turned into the word line WL or the select gate line SGD.

Thereafter, although not illustrated, the insulating layer NL and the insulating layer OL are processed into a stepped shape in a part of regions of the stacked body LMsb. Similarly to the processing on the stacked body LMsa as described above, such processing can be carried out by repeating slimming of mask patterns in photoresist layers and the like and etching of the insulating layer NL and the insulating layer OL of the stacked body LMsb multiple times.

At this time, a stepped shape is formed with the topmost step of stepped portions formed in the stacked body LMsa being close to the bottommost step of stepped portions formed in the stacked body LMsb such that they are continuous from the lower layer side of the stacked body LMsa to the upper layer side of the stacked body LMsb. In this way, the stacked bodies LMsa and LMsb are formed with the stepped regions SR formed therein that have stepped shapes on opposite ends in the X-direction extending from the stacked body LMsa to the stacked body LMsb.

Thereafter, the stepped shapes on opposite ends in the X-direction are further covered with a part of the above-described insulating layer 50 (see the part (a) of FIG. 1).

As illustrated in the part (b) of FIG. 4, a plurality of memory holes MHb that pass through the stacked body LMsb and are respectively connected to the plurality of pillars PLc formed in the stacked body LMsa are formed. The memory holes MHb are portions that are to be upper structures of the pillars PL later.

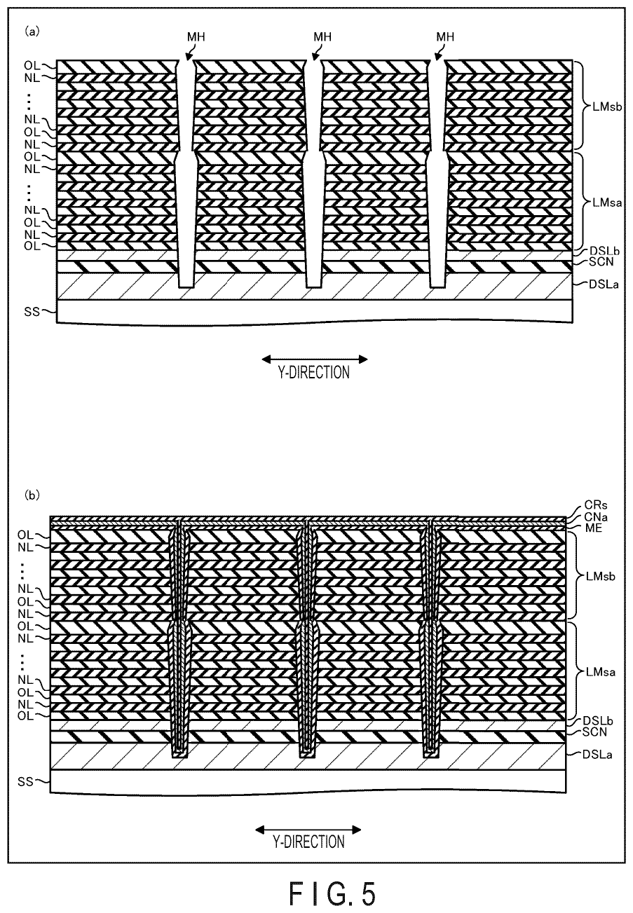

As illustrated in the part (a) of FIG. 5, the sacrificial layer 26 is removed from the pillar PLc at the bottom of the memory hole MHb. In this way, the memory hole MHa is opened at the bottom of each of the plurality of memory holes MHb, so that a plurality of memory holes MH that pass through the stacked bodies LMsb and LMsa, the upper source line DSLb, and the intermediate sacrificial layer SCN and reach the lower source line DSLa are formed.

In a case in which the sacrificial layer 26 filling the pillar PLc is a CVD carbon layer and the like, the sacrificial layers 26 can collectively be removed from the pillars PLc when mask patterns and the like used to form the memory holes MHb in the part (b) of FIG. 4 described above are removed through ashing and the like by using oxygen plasma.

As illustrated in the part (b) of FIG. 5, on the side wall and the bottom surface, in which the lower source line DSLa is exposed, of the memory hole MH, the memory layer ME that includes the block insulating layer BK, the charge accumulation layer CT, and the tunnel insulating layer TN from the side wall side of the memory hole MH in this order(see the parts (b) and (c) of FIG. 2) is formed. The memory layer ME is also formed on the upper surface of the stacked body LMsb.

Furthermore, a channel layer CNa and a core layer CRs are formed in the memory hole MH in this order. In this way, the channel layer CNa is formed on the memory layer ME that covers the side surface and the bottom surface of the memory hole MH and the center portion of the memory hole MH is filled with the core layer CRs. The channel layer CNa and the core layer CRs are also formed on the upper surface of the stacked body LMsb in this order with the memory layer ME in between.

The channel layer CNa is a semiconductor layer that is to be the channel layer CN later. At this point, the entire channel layer CNa is, for example, a non-crystalline semiconductor layer such as an amorphous silicon layer. Furthermore, at this point, the channel layer CNa is formed as being thicker than the channel layer CN of the final pillar PL. Furthermore, at this point, the core layer CRs thus formed is a temporary core layer CRs that is to be removed later.

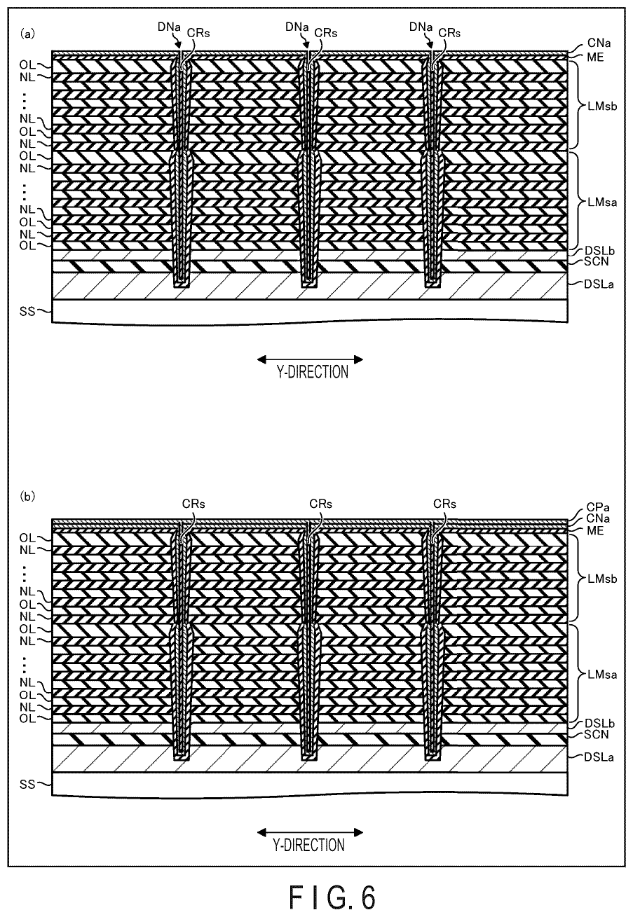

As illustrated in the part (a) of FIG. 6, the core layer CRs formed on the upper surface of the stacked body LMsb is etched back and removed, and the core layer CRs in the memory hole MH is caused to contract to form a cavity DNa in the upper end portion of the memory hole MH.

As illustrated in the part (b) of FIG. 6, a cap layer CPa is formed over the cavity DNa. At this time, similarly to the channel layer CNa, the cap layer CPa is a non-crystalline semiconductor layer such as an amorphous silicon layer. At this point, the cap layer CPa thus formed is a temporary cap layer CPa that is to be removed later. The cap layer CPa is also formed on the upper surface of the stacked body LMsb with the memory layer ME and the channel layer CNa in between.

When the cap layer CPa is formed, an additive of at least any of nitrogen, boron, and carbon may be added to the cap layer CPa. In this case, the additive concentration in the cap layer CPa is preferably lower than the additive concentration in the semiconductor layer CNn.

Thereafter, the channel layer CNa is crystallized to form, for example, a single crystal channel layer CN. To crystallize the channel layer CNa, during the channel layer CNa and the cap layer CPa are formed through processing in FIGS. 5 and 6 described above, a semiconductor layer that contains elements such as carbon, nitrogen, oxygen, or fluorine at high concentration is formed beforehand at an interface between the layers. In this way, the crystallization of the channel layer CNa is controlled.

Hereinafter, FIG. 7 illustrates a detailed example of a way of crystallizing the channel layer CNa.

As illustrated in the part (a) of FIG. 7, the memory layer ME, the core layer CRs, the channel layer CNa, a semiconductor layer CNna, and the cap layer CPa are formed in the memory hole MH through processing in FIGS. 5 and 6 described above.

The semiconductor layer CNna is formed by, for example, adding an additive of at least any of carbon, nitrogen, oxygen, and fluorine to source gas for the semiconductor layer in final stages during the channel layer CNa is formed by a chemical vapor deposition (CVD) method and the like. The semiconductor layer CNna is a layer that is to be the semiconductor layer CNn later and, at this point, is a non-crystalline semiconductor layer such as an amorphous silicon layer.

Thereafter, as described above, the core layer CRs in the memory hole MH is caused to contract. At this time, the semiconductor layer CNna may be etched back along with the core layer CRs. In this way, the cap layer CPa is formed over the cavity DNa (see the part (a) of FIG. 6) generated on the upper end portion of the memory hole MH as described above.

A metal layer NS such as a nickel layer is formed on the upper surface of the cap layer CPa that fills the cavity DNa of the memory hole MH and is formed to cover the upper surface of the stacked body LMsb, as described above, and the entire support substrate SS is subjected to heating for carrying out annealing. At this time, the temperature for the annealing is sufficiently low to the extent that, for example, crystallization does not progress in the channel layer CNa alone.

On the other hand, the metal layer NS formed on the upper surface of the cap layer CPa combines at least partially with silicon and the like of the cap layer CPa to undergo silicidation. Such silicide such as nickel silicide serves to facilitate crystallization of the cap layer CPa and the channel layer CNa. That is, the silicide functions as a catalyst for crystallization of the channel layer CNa and the like. Furthermore, in a case in which an additive of at least any of nitrogen, boron, and carbon is added to the cap layer CPa, the additive facilitates the formation of silicide.

This allows crystallization to start in the depth direction from the upper surface of the cap layer CPa that is in contact with the metal layer NS even during annealing at a low temperature.

As illustrated in the part (b) of FIG. 7, crystallization, which has started from the upper surface of the cap layer CPa, reaches the semiconductor layer CNna below the cap layer CPa. A part of silicide that is a catalyst for crystallization of the cap layer CPa becomes metal fragments NSf, each of which is a minute piece, and diffuses into the cap layer CPa and the semiconductor layer CNna.

The portions of the cap layer CPa and the semiconductor layer CNna where the metal fragments NSf have entered change into a cap layer CPc and the semiconductor layer CNn, which are, for example, a single crystal silicon layer. In this way, crystallization progresses into the cap layer CPc and the semiconductor layer CNn, and the thickness of the metal layer NS on the upper surface of the cap layer CPc is reduced.

Here, the semiconductor layer CNna contains an additive of elements such as carbon, nitrogen, oxygen, or fluorine at high concentration as described above. Since such an additive is contained at high concentration, the semiconductor layer CNna has a function of lowering the rate of crystallization. This facilitates agglomeration of the metal fragments NSf in the semiconductor layer CNna and allows the metal fragments NSf agglomerated at high concentration to reach the channel layer CNa side as crystallization progresses downward of the semiconductor layer CNna.

The metal fragments NSf agglomerated at high concentration cause the rate of crystallization to increase again in the channel layer CNa, so that crystallization can progress in a more homogeneous manner. Accordingly, it is possible to obtain the channel layer CN that is a single crystal silicon layer and the like with high crystallinity.

The process of crystallizing the channel layer CNa, the semiconductor layer CNna, and the cap layer CPa through low-temperature annealing with silicide NS and the like being as a catalyst as described above is also referred to as metal-assisted annealing.

As illustrated in the part (c) of FIG. 7, metal-assisted annealing ends when crystallization of the channel layer CNa progresses, and the entire channel layer CNa becomes the channel layer CN that is, for example, single crystal. The metal layer NS on the upper surface of the cap layer CPc may be allowed to disappear at least to the end of the annealing.

Here, polycrystalline semiconductors and the like may be contained in the channel layer CN, the semiconductor layer CNn, and the cap layer CPc due to, for example, partially incomplete crystallization. However, even in this case, the channel layer CN, the semiconductor layer CNn, and the cap layer CPc that include single crystal semiconductors as a main component are formed through the metal-assisted annealing.

As illustrated in the part (d) of FIG. 7, the metal fragments NSf are segregated in the channel layer CN after crystallization. For removing the metal fragments NSf, a gettering layer GT that is an amorphous silicon layer and the like is formed on the upper surface of the cap layer CPc.

As illustrated in the part (e) of FIG. 7, performing annealing causes the metal fragments NSf segregated in the channel layer CN to move into the gettering layer GT. In this way, it is possible to remove a majority of the metal fragments NSf in the channel layer CN.

As illustrated in the part (f) of FIG. 7, the gettering layer GT is removed.

In metal-assisted annealing, the thicker the layer subjected to crystallization, the more the crystallization is facilitated. Accordingly, as described above, the channel layer CNa is formed as being thicker than the channel layer CN of the final pillar PL. Accordingly, after the channel layer CN is obtained by crystallizing the channel layer CNa, the channel layer CN is subjected to slimming as described below.

As illustrated in the part (g) of FIG. 7, the cap layer CPc is removed to form a cavity DNb on the upper end portion of the memory hole MH.

As illustrated in the part (h) of FIG. 7, the core layer CRs is removed, and the channel layer CN exposed in a cavity DNc thus formed is subjected to slimming to obtain a layer thickness that is to be of the final pillar PL.

As illustrated in the part (i) of FIG. 7, the cavity DNc surrounded by the channel layer CN is filled with the core layer CR, and the cap layer CP is formed over the cavity DNb on the upper end portion of the memory hole MH. The cap layer CP thus formed is, for example, a polycrystalline semiconductor layer such as a polysilicon layer. At this time, a part of the cap layer CP may contain a non-crystalline semiconductor such as of amorphous silicon.

However, even when amorphous silicon or the like is contained in a part of the cap layer CP, the cap layer CP may be subjected to various thermal histories through various processes that follow in manufacturing processes of the semiconductor storage device 1, so that the ratio of non-crystalline portions in the cap layer CP decreases from that of when the cap layer CP has originally been formed. Alternatively, in the semiconductor storage device 1 of a final product, the non-crystalline portions may be allowed to disappear.

In this way, the channel layer CN that is a semiconductor layer such as of single crystal is formed.

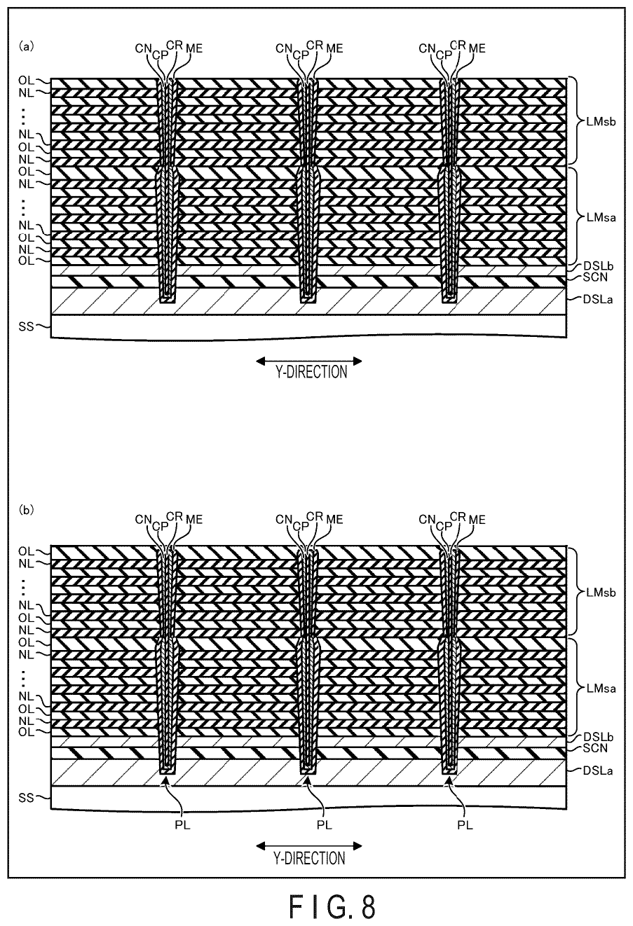

As illustrated in the part (a) of FIG. 8, the cap layer CP, the channel layer CN, and the memory layer ME on the upper surface of the stacked body LMsb are removed by CMP and the like along with a part of the topmost insulating layer OL of the stacked body LMsb.

As illustrated in the part (b) of FIG. 8, the topmost insulating layer OL of the stacked body LMsb, the thickness of which has been reduced by CMP and the like, is extended. In this way, the pillar PL is formed with the cap layer CP buried under the topmost insulating layer OL. It is noted that at this point, the memory layer ME covers the entire side wall of the pillar PL without a part of the side surface of the channel layer CN being exposed from the memory layer ME.

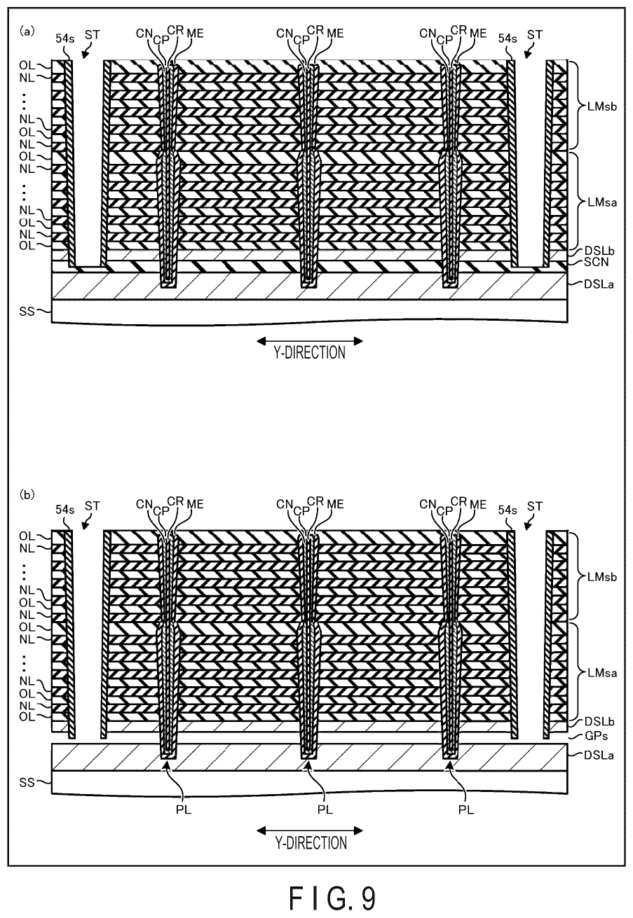

As illustrated in the part (a) of FIG. 9, a slit ST that passes through the stacked bodies LMsb and LMsa, in which the pillars PL are formed, and the upper source line DSLb and reaches the intermediate sacrificial layer SCN is formed. Furthermore, an insulating layer 54s is formed on side walls facing each other in the Y-direction of the slit ST. The slit ST also extends through the stacked bodies LMsa and LMsb in a direction along the X-direction.

As illustrated in the part (b) of FIG. 9, a remover for the intermediate sacrificial layer SCN, for example, hot phosphoric acid is caused to flow through the slit ST with its side walls being protected by the insulating layer 54s to remove the intermediate sacrificial layer SCN between the lower source line DSLa and the upper source line DSLb.

In this way, a gap layer GPs is formed between the lower source line DSLa and the upper source line DSLb. Furthermore, a part of the memory layer ME on the outer peripheral portion of the pillar PL is exposed in the gap layer GPs. At this time, the side walls of the slit ST are protected by the insulating layer 54s, so that the insulating layers NL in the stacked bodies LMsa and LMsb are prevented from being removed.

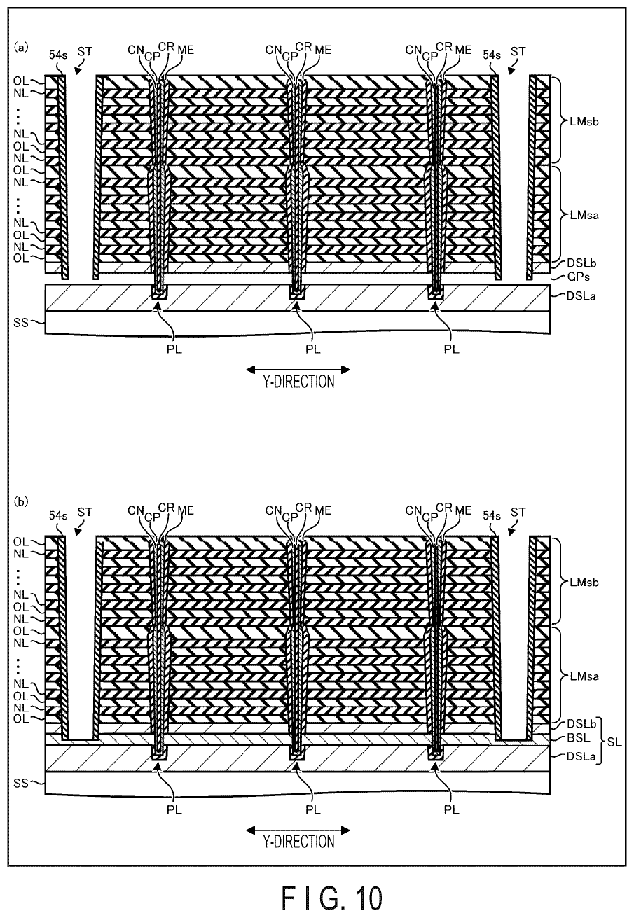

As illustrated in the part (a) of FIG. 10, liquid chemicals are caused to flow through the slit ST into the gap layer GPs as appropriate to sequentially remove the block insulating layer BK, the charge accumulation layer CT, and the tunnel insulating layer TN (see the parts (b) and (c) of FIG. 2) of the memory layer ME exposed in the gap layer GPs. In this way, the memory layer ME is removed from a part of the side wall of the pillar PL, so that a part of the channel layer CN inside is exposed in the gap layer GPs.

As illustrated in the part (b) of FIG. 10, source gas, for example, amorphous silicon is injected from the slit ST with its side walls being protected by the insulating layer 54s to fill the gap layer GPs with amorphous silicon and the like. Furthermore, the support substrate SS is heated to make amorphous silicon filled in the gap layer GPs polycrystalline, so that the intermediate source line BSL that contains polysilicon and the like is formed.

In this way, a part of the channel layer CN of the pillar PL is connected at its side surface to the source line SL with the intermediate source line BSL in between.

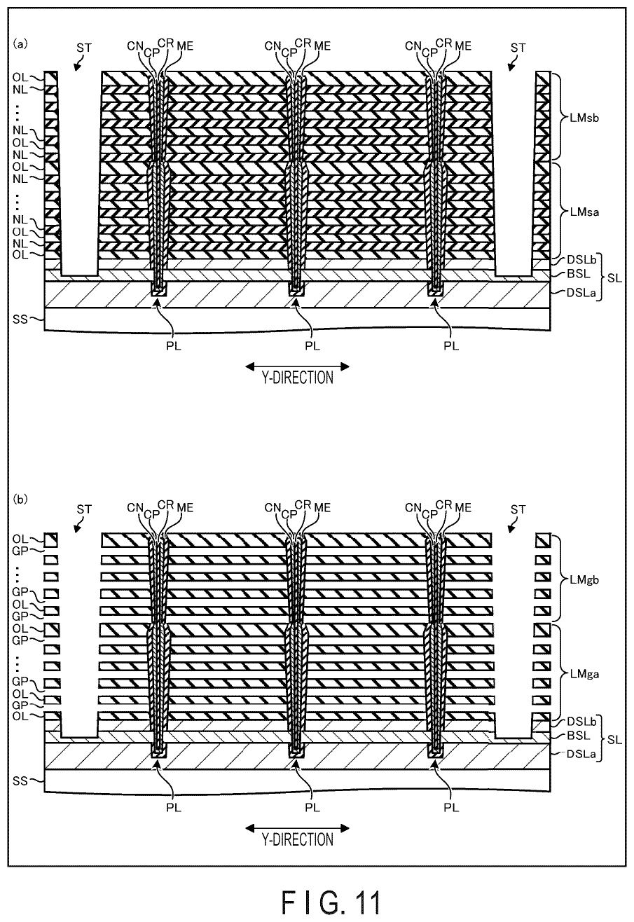

As illustrated in the part (a) of FIG. 11, the insulating layer 54s on the side wall of the slit ST is removed.

As illustrated in the part (b) of FIG. 11, a remover for the insulating layer NL, for example, hot phosphoric acid is caused to flow from the slit ST with the insulating layer 54s being removed into the stacked bodies LMsa and LMsb to remove the insulating layer NL of the stacked bodies LMsa and LMsb. In this way, stacked bodies LMga and LMgb, which include a plurality of gap layers GP as a result of removing the insulating layers NL between the insulating layers OL, are formed.

The stacked bodies LMga and LMgb that include the plurality of gap layers GP have a fragile structure. The plurality of pillars PL support such fragile stacked bodies LMga and LMgb. In this way, the insulating layer OL remaining in the stacked bodies LMga and LMgb is prevented from deflecting or the stacked bodies LMga and LMgb is prevented from warping or collapsing.

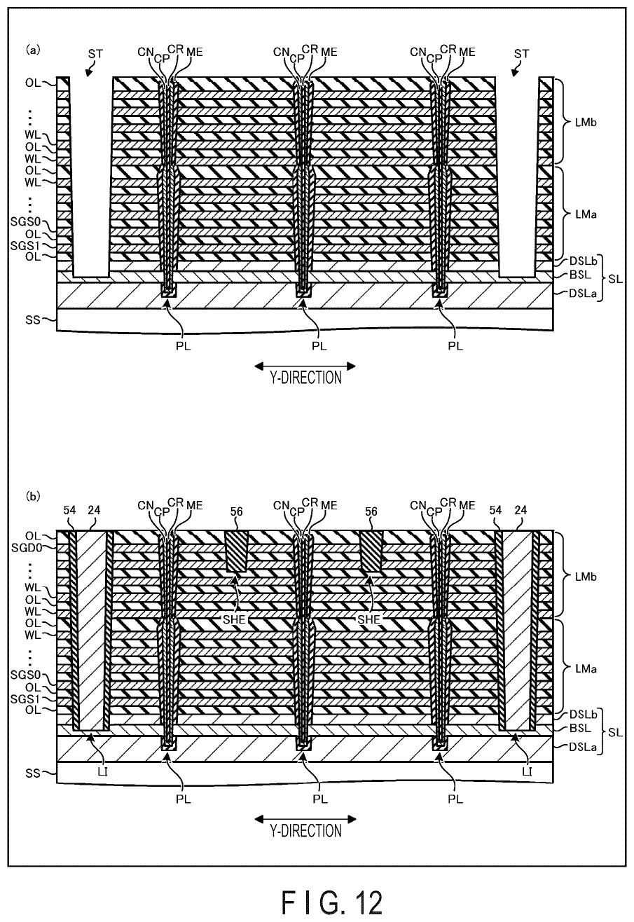

As illustrated in the part (a) of FIG. 12, source gas for a conductive material, for example, tungsten or molybdenum is injected from the slit ST into the stacked bodies LMga and LMgb to fill a gap layer GP of the stacked bodies LMga and LMgb with a conductive material, so that the plurality of word lines WL and the like are formed. In this way, the stacked body LM including the stacked bodies LMa and LMb of the plurality of word lines WL and the like and the plurality of insulating layers OL stacked alternately, with one word line on top of one insulating layer, or vice versa is formed.

The process of forming the intermediate source line BSL from the intermediate sacrificial layer SCN and the process of forming the word line WL from the insulating layer NL as described above are also referred to as a replacing process.

As illustrated in the part (b) of FIG. 12, the slit ST is filled with the conductive layer 24 with the insulating layer 54 in between to form the plate-shaped contact LI. Furthermore, a trench that passes through one or more conductive layers including the topmost conductive layer of the stacked body LMb is formed and the trench is filled with an insulating layer 56 to form the separating layer SHE that partitions the conductive layers into patterns of the select gate line SGD.

Thereafter, although not illustrated, the plurality of contacts CC are formed from the upper side of the stepped region SR, so that each of the contacts reaches the word line WL and the select gate lines SGD and SGS that present each step of a stepped structure of the stepped region SR.

Furthermore, after an insulating layer 52 that covers the stacked body LM is formed, the plug CH that passes through the topmost insulating layer OL of the stacked body LM and the insulating layer 52 and is connected to the cap layer CP on the upper end portion of the pillar PL is formed. Furthermore, the insulating layer 53 that covers the insulating layer 52 is formed, and the bit line BL to which the individual plug CH is connected is formed in the insulating layer 53.

The plug CH, the bit line BL, and the like may be collectively formed by using, for example, dual damascene method.

The peripheral circuit CBA is formed, and covered with the insulating layer 40, on the semiconductor substrate SB that is separate from the support substrate SS on which the stacked body LM is formed. Contacts, vias, wires, and the like are formed in the insulating layer 40 for bringing out the peripheral circuit CBA on the surface of the insulating layer 40 and are connected to electrode pads and the like formed on the upper surface of the insulating layer 40.

Subsequently, the support substrate SS and the semiconductor substrate SB are bonded by the insulating layers 50 and 40 of each of the substrates, and the electrode pads in the insulating layers 50 and 40 are connected. Thereafter, the support substrate SS is removed to expose the source line SL, and the electrode film EL is connected with the insulating layer 60 in which plugs PG are formed in between.

The semiconductor storage device 1 of the embodiment is manufactured as described above. (Recap)

For semiconductor storage devices such as three-dimensional non-volatile memories, there is a technique of making a channel layer of a pillar monocrystalline. This improves carrier mobility in the channel layer and makes it possible to reduce noise because of reduced possibility of trapping due to grain boundaries. Crystallization of a channel layer is carried out by metal-assisted annealing in which, for example, metal elements such as nickel are introduced into the non-crystalline channel layer as catalysts.

During crystallization of a channel layer, however, crystallization may stop progressing at a certain probability, which may cause polycrystalline portions to be mixed in the channel layer. Such stoppage of crystallization may be caused by an effect of microcrystals of silicon and the like generated at an interface between a non-crystalline channel layer and a memory layer, and concentration reduction of nickel silicide and the like that serves as a catalyst occurring along with the progress of crystallization, and the like. Any variation in crystallinity of a channel layer such as due to presence of polycrystalline may lead to variation in memory cell characteristics such as cell current, threshold voltage, operational speed of write and read, and the like.

According to the semiconductor storage device 1 of the embodiment, among the channel layer CN, the semiconductor layer CNn, and the cap layer CP, the semiconductor layer CNn contains an additive of at least any of carbon, nitrogen, oxygen, and fluorine. In this way, it is possible in metal-assisted annealing to lower the rate of crystallization in the semiconductor layer CNn and cause agglomeration of silicide that is a catalyst for crystallization. Accordingly, it is possible to prevent stagnant crystallization in the channel layer CN and improve crystallinity of the channel layer CN.

According to the semiconductor storage device 1 of the embodiment, the semiconductor layer CNn is located above the height position of the word line WL one layer below the select gate lines SGD0 and SGD1 through which the separating layer SHE passes. A high-concentration additive of carbon and the like may hinder crystallization of the channel layer CN and the like and deteriorate characteristics of the memory cell MC, and therefore, the semiconductor layer CNn that contains carbon and the like is arranged above the topmost word line WL of the stacked body LM, so that crystallization of the channel layer CN is prevented from being hindered at the height position of the word line WL and it is possible to prevent characteristics of the memory cell MC from deteriorating.

According to the semiconductor storage device 1 of the embodiment, the semiconductor layer CNn is arranged at the height position above the topmost select gate line SGD0 of the stacked body LM. In this way, it is possible to reliably prevent characteristics of the memory cell MC from deteriorating.

According to the semiconductor storage device 1 of the embodiment, the channel layer CN does not contain any additive. Since any additive that can hinder crystallization of carbon and the like is not contained in the channel layer CN, it is possible to further improve characteristics of the memory cell MC.

According to the semiconductor storage device 1 of the embodiment, the concentration of the additive contained in the semiconductor layer CNn is 1×10²⁰ cm⁻³ or more and 3×10²¹ cm⁻³ or less, preferably 5×10²⁰ cm⁻³ or more and 2×10²¹ cm⁻³ or less, and more preferably 9×10²⁰ cm⁻³ or more and 1.5×10²¹ cm⁻³ or less. In this way, it is possible to lower the rate of crystallization in the semiconductor layer CNn and to reliably cause agglomeration of silicide.

In the embodiment described above, the semiconductor storage device 1 includes the stacked body LM of two-tier structure in which two stacked bodies LMa and LMb stacked one over another. However, the configuration of the stacked body is not limited to two tiers, and it may be one tier or may be three tier or more.

Furthermore, in the embodiment described above, the pillar PL is connected to the source line SL on the side surface of the channel layer CN, whereas this is not a limitation. For example, the pillar may be configured to be connected to the source line at the lower end portion of the channel layer by removing the memory layer on the bottom surface of the pillar.

Furthermore, in the embodiment described above, the peripheral circuit CBA is arranged above the stacked body LM. However, the peripheral circuit may be arranged below the stacked body, or alternatively, it may be arranged on the same layer as the stacked body. In a case in which the peripheral circuit is arranged below the stacked body, the stacked body and the like can be formed immediately above the semiconductor substrate on which the peripheral circuit is formed. Furthermore, in a case in which the peripheral circuit is arranged on the same layer as the stacked body, the stacked body can be formed at a position different from the peripheral circuit on the semiconductor substrate on which the peripheral circuit is formed.

While certain embodiments have been described, these embodiments have been presented by way of example only, and are not intended to limit the scope of the inventions. Indeed, the novel devices and methods described herein may be embodied in a variety of other forms; furthermore, various omissions, substitutions, and changes in the form of the embodiments described herein may be made without departing from the spirit of the inventions. The accompanying claims and their equivalents are intended to cover such forms or modification as would fall within the scope and spirit of the inventions.

What is claimed is

1. A semiconductor storage device, comprising:
a stacked body including a plurality of conductive layers and a plurality of insulating layers that are stacked alternately with each other; and
a pillar extending in the stacked body in a stacked direction of the stacked body, wherein
the pillar includes:
a first semiconductor layer extending in the stacked body in the stacked direction;
a second semiconductor layer above the first semiconductor layer; and
a third semiconductor layer interposed between the first and second semiconductor layers, and
the third semiconductor layer contains an additive of at least one of carbon, nitrogen, oxygen, and fluorine.

2. The semiconductor storage device of claim 1, further comprising:
a separating layer that passes at least through a topmost conductive layer of the stacked body but does not pass through all of the plurality of conductive layers in the stacked direction and that extends in a first direction that intersects with the stacked direction, wherein
the third semiconductor layer is located above a height position of an uppermost conductive layer among the plurality of conductive layers that is not passed through by the separating layer.

3. The semiconductor storage device of claim 2, wherein the separating layer passes through two or more of the plurality of conductive layers.

4. The semiconductor storage device of claim 2, wherein
the plurality of conductive layers comprise a plurality of word lines and one or more select gate lines above the plurality of word lines, and
the third semiconductor layer is above an uppermost one of the word lines.

5. The semiconductor storage device of claim 4, wherein the third semiconductor layer is above an uppermost one of the one or more select gate lines.

6. The semiconductor storage device of claim 1, wherein each of the first and third semiconductor layers includes a single crystal semiconductor as a main component.

7. The semiconductor storage device of claim 1, wherein the second semiconductor layer includes polycrystal as a main component.

8. The semiconductor storage device of claim 1, wherein a concentration of the additive contained in the third semiconductor layer is
1×10²⁰ cm⁻³ or more and 3×10²¹ cm⁻³ or less.

9. The semiconductor storage device of claim 1, wherein a concentration of the additive contained in the third semiconductor layer is
9×10²⁰ cm⁻³ or more and 1.5×10²¹ cm⁻³ or less.

10. The semiconductor storage device of claim 1, wherein the first semiconductor layer comprises a channel layer.

11. The semiconductor storage device of claim 1, wherein the third semiconductor layer is in direct contact with the first semiconductor layer.

12. The semiconductor storage device of claim 1, wherein the third semiconductor layer is in direct contact with the second semiconductor layer.

13. The semiconductor storage device of claim 1, wherein a thickness of the third semiconductor layer is less than a thickness of the second semiconductor layer.

14. The semiconductor storage device of claim 1, wherein
the pillar further includes a core layer around which the first semiconductor layer is formed, and
the third semiconductor layer is in contact with an outer side surface of the core layer.

15. The semiconductor storage device of claim 14, wherein an upper surface of the core layer and an upper surface of the third semiconductor layer are flush with each other.

16. The semiconductor storage device of claim 14, wherein
the pillar further includes a tunnel insulating layer around the first semiconductor layer and the third semiconductor layer, and a charge accumulation layer around the tunnel insulating layer, and
the third semiconductor layer is in contact with an inner side surface of the tunnel insulating layer.

17. A manufacturing method of a semiconductor storage device, comprising:
forming a stacked body including a plurality of sacrificial layers and a plurality of insulating layers that are stacked alternately with each other;
forming a memory hole extending in the stacked body in a stacked direction of the stacked body; and
forming, in the memory hole, a pillar including a first semiconductor layer extending in the stacked body in the stacked direction and a second semiconductor layer above the first semiconductor layer, wherein
said forming the pillar comprises:
crystallizing the first semiconductor layer by subjecting the first semiconductor layer to annealing; and
before the annealing, forming a third semiconductor layer that contains an additive to lower a rate of crystallization on an upper end portion of the first semiconductor layer.

18. The manufacturing method of a semiconductor storage device of claim 17, wherein the annealing is metal-assisted annealing.

19. The manufacturing method of a semiconductor storage device of claim 17, wherein said forming the third semiconductor layer comprises adding at least one of carbon, nitrogen, oxygen, and fluorine to the third semiconductor layer as the additive.

20. The manufacturing method of a semiconductor storage device of claim 17, wherein said forming the pillar comprises forming the first semiconductor layer, the third semiconductor layer, and a fourth semiconductor layer in this order;
performing the annealing to crystallize the first, third, and fourth semiconductor layers;
removing the crystalized fourth semiconductor layer; and
forming the second semiconductor layer on an upper end portion of the third semiconductor layer, the second semiconductor layer including a polycrystal as a main component.
